(19) United States
(12) Patent Application Publication
(10) Pub. No.: US 2025/0264535 A1
(43) Pub. Date: Aug. 21, 2025

(54) BATTERY DIAGNOSIS METHOD AND APPARATUS

(71) Applicant: MONA INC., Jeollabuk-do (KR)

(72) Inventor: Yu Sung KIM, Seoul (KR)

(73) Assignee: MONA INC., Jeollabuk-do (KR)

(21) Appl. No.: 18/444,777

(22) Filed: Feb. 19, 2024

(51) Int. Cl. G01R 31/367; G01R 31/389

(52) U.S. Cl. CPC G01R 31/367; G01R 31/389

(57) ABSTRACT

Provided are a battery diagnosis method and apparatus. The battery diagnosis apparatus trains a first model by using training data in which at least one frequency band and a characteristic impedance component of a learning battery mapped to each frequency band are labeled as a basic equivalent circuit of the learning battery, and in response to receiving a target impedance component measured by applying the at least one frequency band to a target battery, generates a predicted equivalent circuit of the target battery to be used for battery diagnosis by inputting the target impedance component to the first model. The disclosure was supported by the Ministry of Trade, Industry and Energy (Project Number: P0023243, Project Number (NTIS):1425182671).

### BACKGROUND

### 1. Field

The disclosure relates to a battery diagnosis method and apparatus, and more particularly, to a method and apparatus for diagnosing a state of a battery by using battery impedance information measured in a certain frequency band.

The disclosure was supported by the Ministry of Trade, Industry and Energy (Project Number: P0023243, Project Number (NTIS):1425182671).

### 2. Description of the Related Art

Batteries are used in various fields such as electric vehicles and energy storage systems (ESS). Rechargeable batteries (e.g., secondary batteries) deteriorate due to various factors such as a period of use or a usage environment. Batteries with a certain level of deterioration or more need to be replaced. In order to replace a battery, it is necessary to accurately determine a state of the battery. Methods of determining a state of a battery include a method of sequentially applying frequencies in a certain range to a battery and measuring an impedance. For example, conventional electrochemical impedance spectroscopy (EIS) is disadvantageous in that it takes a lot of time to measure a battery impedance because an impedance is measured for each frequency by applying all frequencies from low to high frequencies to a battery at regular intervals.

### SUMMARY

Provided are a method and apparatus for diagnosing a state of a battery by using impedance information measured in a certain frequency band.

Additional aspects will be set forth in part in the description which follows and, in part, will be apparent from the description, or may be learned by practice of the presented embodiments.

According to an aspect of the disclosure, a battery diagnosis method includes training a first model by using training data in which at least one frequency band and a characteristic impedance component of a learning battery mapped to each frequency band are labeled as a basic equivalent circuit of the learning battery, receiving a target impedance component measured by applying the at least one frequency band to a target battery, and generating a predicted equivalent circuit of the target battery to be used for battery diagnosis by inputting the target impedance component to the first model.

According to another aspect of the disclosure, a battery diagnosis apparatus includes a first model configured to output a predicted equivalent circuit in response to receiving at least one frequency band and a battery impedance component of each frequency band, an input unit configured to receive a target impedance component measured by applying the at least one frequency band to a target battery, and an equivalent circuit generation unit configured to generate a predicted equivalent circuit of the target battery to be used for battery diagnosis by inputting the target impedance component to the first model.

### BRIEF DESCRIPTION OF THE DRAWINGS

The above and other aspects, features, and advantages of certain embodiments will be more apparent from the following description taken in conjunction with the accompanying drawings, in which:

FIG. 1 is a diagram illustrating an example of a battery diagnosis apparatus, according to an embodiment;

FIG. 2 is a diagram illustrating an overall process of battery diagnosis, according to an embodiment;

FIG. 3 is a diagram illustrating an example of a frequency band used in a battery diagnosis apparatus, according to an embodiment;

FIG. 4 is a diagram illustrating an example of a method of defining a frequency band used for battery diagnosis, according to an embodiment;

FIG. 5 is a diagram illustrating an example of a battery equivalent circuit, according to an embodiment;

FIG. 6 is a diagram illustrating an example of a method of training a model used for battery diagnosis, according to an embodiment;

FIG. 7 is a flowchart illustrating an example of a battery diagnosis method, according to an embodiment; and

FIG. 8 is a diagram illustrating a configuration of an example of a battery diagnosis apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, a battery diagnosis method and apparatus according to an embodiment will be described in detail with reference to the accompanying drawings.

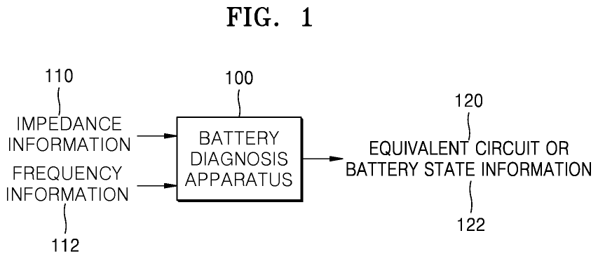

FIG. 1 is a diagram illustrating an example of a battery diagnosis apparatus, according to an embodiment.

Referring to FIG. 1, when a battery diagnosis apparatus 100 receives battery impedance information 110 measured by applying a frequency of a predefined frequency band 112 to a battery, the battery diagnosis apparatus 100 outputs an equivalent circuit 120 of the battery or state information 122 of the battery. Hereinafter, a battery to undergo state diagnosis is referred to as a ‘target battery’.

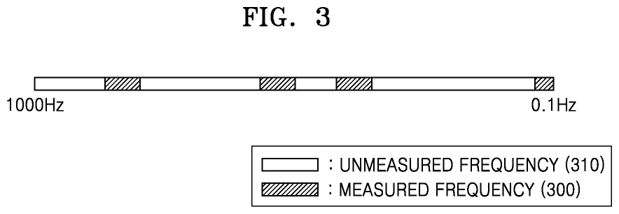

The battery diagnosis apparatus 100 receives the impedance information 110 measured by applying a certain frequency band, rather than an entire frequency range used in conventional EIS, to a target battery. For example, an impedance measured by applying, to the target battery, only a frequency 300 of a certain band in an entire frequency range used in EIS is used as shown in FIG. 3. Accordingly, compared to a conventional EIS method of obtaining an impedance by applying an entire frequency range to a target battery, the present embodiment may reduce a time taken for battery diagnosis. In the present embodiment, a frequency band refers to a band including at least one frequency. For example, a frequency band may include one frequency value or multiple frequency values.

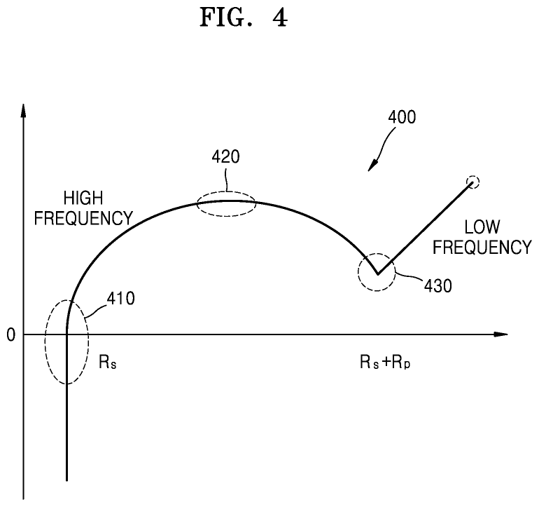

The reason why EIS uses an impedance measured for an entire frequency range is that an exact state of a target battery may not be determined with only impedance information measured in a certain frequency band. Accordingly, the present embodiment proposes a characteristic frequency band that may well reflect characteristics of a target battery rather than using a frequency at an arbitrary position in an entire frequency range. In the present embodiment, a method of setting a characteristic frequency band used for impedance measurement will be described below with reference to FIG. 4.

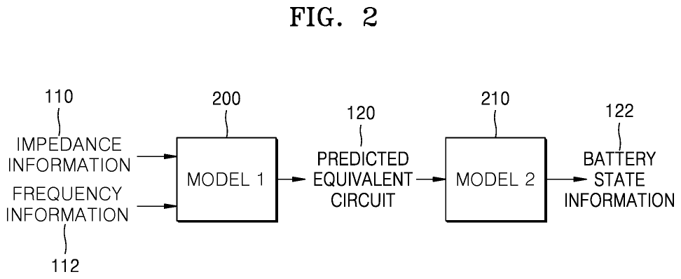

In an embodiment, when the battery diagnosis apparatus 100 receives the impedance information 110 for at least one frequency band 112, the battery diagnosis apparatus 100 may output the battery equivalent circuit 120 for battery diagnosis. An artificial intelligence model may be used as a method of generating the battery equivalent circuit 120 based on the battery impedance information 110, and an example thereof is shown in FIG. 2.

In another embodiment, when the battery equivalent circuit 120 is generated, the battery diagnosis apparatus 100 may analyze various physical characteristic information such as battery impedance information for an entire frequency range through the battery equivalent circuit 120 and may output the state information 122 of the target battery (e.g., a battery failure or a cause of the failure). A method of outputting the battery state information 122 based on the battery equivalent circuit 120 will be described with reference to FIG. 2.

FIG. 2 is a diagram illustrating an overall process of battery diagnosis, according to an embodiment.

Referring to FIG. 2, the battery diagnosis apparatus 100 includes a first model 200 and a second model 210.

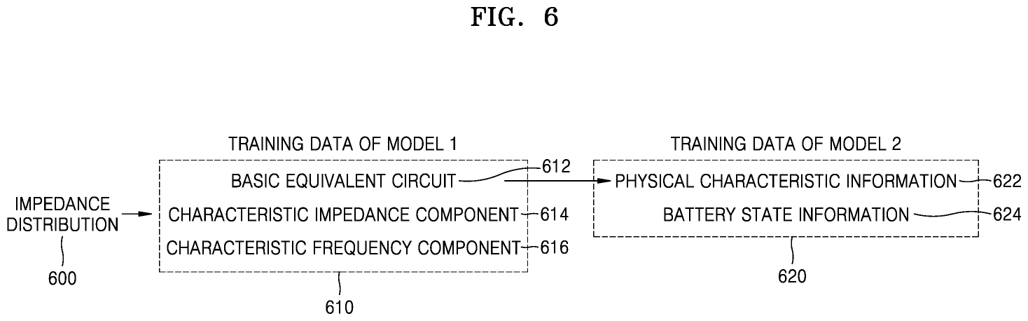

The first model 200 is an artificial intelligence model that outputs an equivalent circuit in response to receiving the impedance information 110 for at least one frequency band 112. The equivalent circuit generated and output by the first model 200 is referred to as a ‘predicted equivalent circuit’ 120. The first model 200 may be implemented through any of various conventional artificial neural networks such as a convolutional neural network (CNN) or an artificial neural network (ANN). A method of training and generating the first model by using training data will be described below with reference to FIG. 6. The present embodiment will be described assuming that the first model 200 is generated after completing learning.

The second model 210 may be an artificial intelligence model or a model defined as a function. In an embodiment, the second model 210 may be an artificial intelligence model or a function model that, when the second model 210 receives the predicted equivalent circuit 120 or physical characteristic information including a battery impedance (e.g., impedance information of an entire frequency range (300+310) identified through the predicted equivalent circuit 120, outputs battery state information 122 (e.g., a battery failure, a cause of the failure, a state of charge (SOC), and a state of health (SOCH)). For example, the second model 210 may be implemented as any of various conventional artificial neural networks such as a CNN or an ANN, or may be implemented as a sigmoid function, a hyperbolic tangent function or an ReLU function. A method of training and generating the second model by using training data will be described below with reference to FIG. 6.

The at least one frequency band 112 input to the first model 200 is predefined. For example, as shown in FIGS. 3 and 4, a frequency band used in the first model 200 is a certain frequency band 300 (see FIG. 3) rather than an entire frequency range of EIS. The battery diagnosis apparatus 100 inputs, to the first model 200, the predefined frequency band 112 and the battery impedance information 110 measured by applying the frequency band 112 to the battery. A method of defining the at least one frequency band 112 input to the first model 200 will be described below with reference to FIG. 4.

The battery diagnosis apparatus 100 determines the battery state information 122 by inputting the predicted equivalent circuit 120 of the target battery generated by using the first model 200 or physical characteristic information such as battery impedance information identified by using the predicted equivalent circuit 120 to the second model 210.

FIG. 3 is a diagram illustrating an example of a frequency band used in a battery diagnosis apparatus, according to an embodiment.

Referring to FIG. 3, the battery diagnosis apparatus 100 uses only the certain frequency band 300 rather than an entire frequency range used in conventional EIS. For example, when an entire frequency range used in battery impedance measurement in conventional EIS is 0.1 Hz to 1000 Hz, in the present embodiment, an impedance is measured only for the certain frequency band 300 and an impedance is not measured for the remaining frequency band 310, thereby reducing a time taken for battery diagnosis.

FIG. 4 is a diagram illustrating an example of a method of defining a frequency band used for battery diagnosis, according to an embodiment.

FIG. 4 is a graph 400 showing a curve of distribution of impedance values measured by applying frequencies from low to high frequencies at regular intervals to a battery on a complex plane. The x-axis is a real axis and the y-axis is an imaginary axis. The impedance distribution graph 400 of the present embodiment may be obtained by connecting a distribution of impedance values measured by using any of various conventional battery impedance measurement methods such as EIS. The impedance distribution graph 400 of the present embodiment is merely an example for helping understanding, and a shape of the impedance distribution graph 400 may vary according to a type of the battery.

The impedance distribution graph 400 shown on the complex plane may include at least one semicircular shape and an ohmic resistance shape. In the impedance distribution of the present embodiment, at least one impedance value existing in a maximum value area 420 and/or a minimum value area 410 of the semicircular shape, and/or a maximum value area and/or a minimum value area 430 of the ohmic resistance area may be extracted as a characteristic impedance value. For example, three impedance values corresponding to a minimum point of the ohmic resistance area, and a maximum point and a minimum point of the semicircular shape, or a plurality of impedance values covering a certain range on the left and right sides of each point may be extracted as characteristic impedance components.

Because the impedance distribution graph 400 is a graph showing an impedance value measured at each frequency on a complex plane, the battery diagnosis apparatus 100 may extract a frequency band corresponding to a characteristic impedance component in the impedance distribution graph 400 as a characteristic frequency component. The battery diagnosis apparatus 100 may determine the characteristic frequency component corresponding to the characteristic impedance component as at least one frequency band used in the battery diagnosis apparatus 100. For example, the battery diagnosis apparatus 100 may determine a plurality of frequencies corresponding to the maximum value area 420 and the minimum value area 410 of the semicircular shape and the minimum value area 430 of the ohmic resistance area as the at least one frequency band 112 input to the first model 200. In the present embodiment, the areas 410, 420, and 430 for extracting a characteristic impedance component are only an example, and various modifications may be made according to embodiments. For example, the battery diagnosis apparatus 100 may automatically extract, through a graph analysis algorithm, a point at which a gradient suddenly changes or a maximum value point or a minimum value point from the impedance distribution graph 400, and may determine a characteristic frequency component.

In another embodiment, to determine a characteristic impedance component and a characteristic frequency component, the impedance distribution graph 400 may be obtained several times. For example, an impedance distribution may be obtained for the same battery several times, or an impedance distribution may be obtained for different batteries of the same type several times. In this case, values of characteristic frequency components in impedance distribution graphs may not match perfectly. In this case, the battery diagnosis apparatus 100 may determine a value of a characteristic frequency component through a statistical method. For example, the battery diagnosis apparatus 100 obtains a normal distribution of characteristic frequency components corresponding to a plurality of characteristic impedance components obtained from a plurality of impedance distributions. The battery diagnosis apparatus 100 may determine a frequency satisfying (μ−2σ<frequency<μ+2σ) based on the normal distribution as a characteristic frequency component.

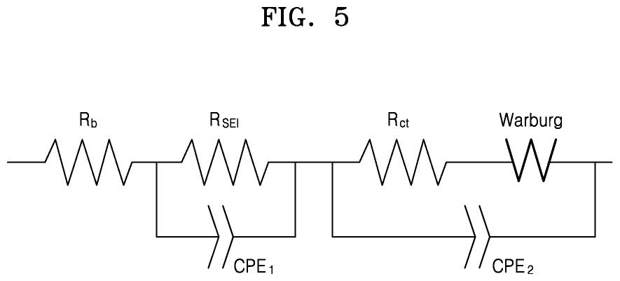

FIG. 5 is a diagram illustrating an example of a battery equivalent circuit, according to an embodiment.

Referring to FIG. 5, the battery diagnosis apparatus 100 may generate a battery equivalent circuit based on the battery impedance distribution of FIG. 4. Hereinafter, the equivalent circuit generated based on the battery impedance distribution of FIG. 4 will be referred to as a ‘basic equivalent circuit’.

In an embodiment, the battery diagnosis apparatus 100 may predefine at least one predefined equivalent circuit template, may select an equivalent circuit template corresponding to a shape of an impedance distribution, may calculate a value of each circuit element of the selected equivalent circuit template (e.g., a resistor, a coil, a capacitor, a constant phase element (CPE), or a Warburg diffusion element), and may generate a basic equivalent circuit. In addition, the battery diagnosis apparatus may generate a basic equivalent circuit through any of various conventional methods such as a Nelder-Mead method, a genetic algorithm, or constrained minimization. A method of obtaining a basic equivalent circuit from impedance distribution information is already known, and thus, an additional description thereof will be omitted.

FIG. 6 is a diagram illustrating an example of a method of training a model used for battery diagnosis, according to an embodiment.

Referring to FIG. 6, the battery diagnosis apparatus 100 generates training data 610 to be used to train the first model 200 through an impedance distribution 600 as shown in FIG. 4. When the battery diagnosis apparatus 100 receives the impedance distribution 600 of a battery measured through EIS or the like, the battery diagnosis apparatus 100 generates a basic equivalent circuit 612 described with reference to FIG. 5 by using the impedance distribution 600 and extracts a characteristic impedance component 614 and a characteristic frequency component 616 described with reference to FIG. 4. The battery diagnosis apparatus 100 generates training data in which the characteristic impedance component 614 and the characteristic frequency component 616 are labeled as the basic equivalent circuit 612. Hereinafter, a battery used for impedance distribution measurement to generate training data is referred to as a ‘learning battery’. The first model 200 is trained through a process of comparing the basic equivalent circuit 612 of the training data 610 with a predicted equivalent circuit output by receiving the training data 610. A method of training an artificial intelligence model by using training data is already known, and thus, an additional description thereof will be omitted.

The battery diagnosis apparatus 100 may generate training data 620 to be used to train the second model 210 by using some of the training data 610 of the first model. For example, the battery diagnosis apparatus 100 identifies physical characteristic information 622 including a battery impedance (e.g., an impedance for an entire frequency range of FIG. 2) through the basic equivalent circuit 612 of the training data 610 of the first model, and uses the physical characteristic information 622 as training data of the second model 210. The physical characteristic information 622 may include various physical quantities that may be determined through circuit analysis in addition to the impedance. The battery diagnosis apparatus 100 generates the training data 620 for the second model by labeling the physical characteristic information 622 as state information 624 of the learning battery (e.g., a battery failure, a cause of the failure, an SOC, and an SOH). The second model 210 is trained through a process of comparing the battery state information 624 existing in the training data 620 of the second model with battery state information output by receiving the training data 620.

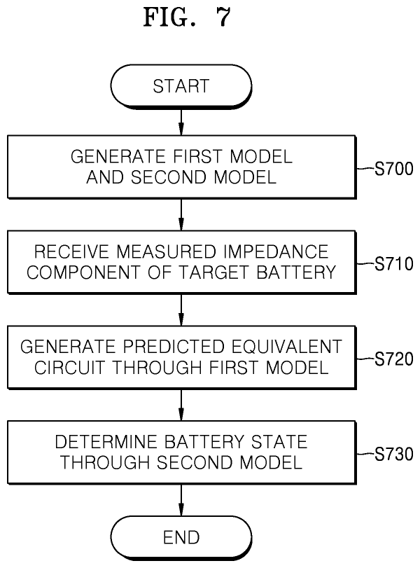

FIG. 7 is a flowchart illustrating an example of a battery diagnosis method, according to an embodiment.

Referring to FIG. 7, the battery diagnosis apparatus 100 generates a first model and a second model (S700). The first model is a model trained by using training data in which at least one frequency band and a characteristic impedance component of a learning battery mapped to each frequency band are labeled as a basic equivalent circuit of the learning battery.

The second model is a model trained by using training data in which physical characteristic information identified by analyzing the basic equivalent circuit of the learning battery is labeled as state information of the learning battery. An example of a method of generating the first model and the second model is illustrated in FIG. 6. In another embodiment, when the first model and the second model are generated in advance through various methods, a process of generating the first model or the second model may be omitted.

The battery diagnosis apparatus 100 receives a target impedance component measured by applying at least one predefined frequency band to a target battery (S710). The at least one frequency band is a frequency corresponding to a characteristic impedance component of a maximum point area or a minimum point area of a semicircular shape, or an ohmic resistance area in a curve of an impedance distribution measured by applying frequencies of an entire range to the learning battery. An example of a method of defining a frequency band used to measure an impedance of the target battery is illustrated in FIG. 4. In an embodiment, the frequency band used to measure the impedance of the target battery may be the same as a characteristic frequency component of FIG. 4 or may be a frequency of a certain range including the characteristic frequency component. For example, when the characteristic frequency component is A Hz, the frequency band used to measure the impedance of the target battery may be A Hz or may include at least one frequency between (A−a) and (A+a).

The battery diagnosis apparatus 100 generates a predicted equivalent circuit of the target battery to be used for battery diagnosis by inputting the target impedance component to the first model (S720). An example of generating a predicted equivalent circuit through the first model is illustrated in FIG. 2.

The battery diagnosis apparatus 100 may determine a state of the target battery by analyzing the predicted equivalent circuit (S730). In an embodiment, the battery diagnosis apparatus 100 may determine a state of the target battery by inputting physical characteristic information identified by analyzing the predicted equivalent circuit to the second model. The physical characteristic information may include battery impedance information, and state information may include whether there is a battery failure and/or a cause of the failure.

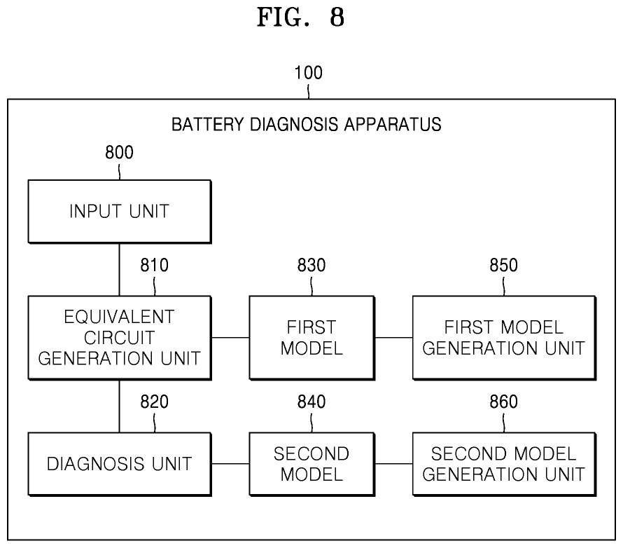

FIG. 8 is a diagram illustrating a configuration of an example of a battery diagnosis apparatus, according to an embodiment.

Referring to FIG. 8, the battery diagnosis apparatus 100 includes an input unit 800, an equivalent circuit generation unit 810, a diagnosis unit 820, a first model 830, a second model 840, a first model generation unit 850, and a second model generation unit 860. When the first model 830 and the second model 840 are generated in advance, the first model generation unit 850 and the second model generation unit 860 may be omitted. In an embodiment, the battery diagnosis apparatus 100 may be implemented as a computing device including a memory, a processor, and an input/output device, and in this case, each element may be implemented as software, may be loaded into the memory, and then may be executed by the processor.

When the first model generation unit 850 receives at least one frequency band and a battery impedance component of each frequency band, the first model generation unit 850 generates the first model 830 that outputs a predicted equivalent circuit. In an embodiment, the first model generation unit 850 may receive an impedance distribution of a learning battery for a frequency of a certain range, may generate a basic equivalent circuit of the learning battery from the impedance distribution, may identify a characteristic frequency component and a characteristic impedance component corresponding to at least one predefined impedance area in the impedance distribution, may generate training data in which the characteristic frequency component and the characteristic impedance component are labeled as the basic equivalent circuit, and may train the first model 830 by using the training data.

When the second model generation unit 860 receives physical characteristic information, the second model generation unit 860 generates the second model 840 that outputs a battery state. In an embodiment, the second model generation unit 860 trains and generates the second model 840 by using training data in which the physical characteristic information identified by analyzing the basic equivalent circuit is labeled as a battery state of the learning battery.

The input unit 800 receives a target impedance component measured by applying at least one frequency band to a target battery. The frequency band corresponds to the characteristic frequency component of the training data used to train the first model.

The equivalent circuit generation unit 810 generates a predicted equivalent circuit of the target battery to be used for battery diagnosis by inputting the target impedance component to the first model 830.

The diagnosis unit 820 determines a battery state of the target battery by inputting physical characteristic information identified by analyzing the predicted equivalent circuit to the second model 840.

The disclosure may also be implemented as computer-readable code on a computer-readable recording medium. The computer-readable recording medium includes any storage device that may store data which may be thereafter read by a computer system. Examples of the computer-readable recording medium include a read-only memory (ROM), a random-access memory (RAM), a compact disk (CD)-ROM, a magnetic tape, a floppy disk, and an optical data storage device. The computer-readable recording medium may also be distributed over network-coupled computer systems so that the computer-readable code is stored and executed in a distributive manner.

The disclosure has been described with reference to the embodiments thereof. It will be understood by one of ordinary skill in the art that various changes in form and details may be made therein without departing from the spirit and scope of the disclosure as defined by the appended claims. Hence, the disclosed embodiments should be considered in descriptive sense only and not for purposes of limitation. The scope of the disclosure is defined only by the following claims, and all the equivalents of the embodiments may also be construed to be in the scope of the disclosure.

According to an embodiment, because a state of a battery may be diagnosed by using impedance information measured in a certain frequency band, a battery inspection time may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure as defined by the following claims.

What is claimed is:

1. A battery diagnosis method comprising:
training a first model by using training data in which at least one frequency band and a characteristic impedance component of a learning battery mapped to each frequency band are labeled as a basic equivalent circuit of the learning battery;
receiving a target impedance component measured by applying the at least one frequency band to a target battery; and
generating a predicted equivalent circuit of the target battery to be used for battery diagnosis by inputting the target impedance component to the first model.

2. The battery diagnosis method of claim 1, wherein the at least one frequency band comprises a frequency corresponding to a maximum point area or a minimum point area of a semicircular shape, or an ohmic resistance area in a curve of an impedance distribution measured by applying frequencies of an entire range to the learning battery.

3. The battery diagnosis method of claim 1, further comprising generating the training data,
wherein the generating of the training data comprises:
receiving an impedance distribution of the learning battery for frequencies of an entire range;
generating a basic equivalent circuit of the learning battery from the impedance distribution;
identifying a characteristic impedance component and a characteristic frequency component corresponding to at least one predefined characteristic impedance area in the impedance distribution; and
labeling the characteristic impedance component and the characteristic frequency component as the basic equivalent circuit.

4. The battery diagnosis method of claim 1, further comprising determining a state of the target battery by analyzing the predicted equivalent circuit.

5. The battery diagnosis method of claim 4, wherein the determining of the state of the target battery comprises:
training a second model by using training data in which physical characteristic information identified by analyzing the basic equivalent circuit is labeled as state information of the learning battery; and
determining a state of the target battery by inputting physical characteristic information identified by analyzing the predicted equivalent circuit to the second model.

6. The battery diagnosis method of claim 5, wherein
the physical characteristic information comprises battery impedance information, and
the state information comprises whether there is a battery failure and/or a cause of the failure.

7. A battery diagnosis apparatus comprising:
a first model configured to output a predicted equivalent circuit in response to receiving at least one frequency band and a battery impedance component of each frequency band;
an input unit configured to receive a target impedance component measured by applying the at least one frequency band to a target battery; and
an equivalent circuit generation unit configured to generate a predicted equivalent circuit of the target battery to be used for battery diagnosis by inputting the target impedance component to the first model.

8. The battery diagnosis apparatus of claim 7, further comprising a first model generation unit configured to train the first model by using training data in which a characteristic impedance component and a characteristic frequency component of a learning battery are labeled as a basic equivalent circuit of the learning battery.

9. The battery diagnosis apparatus of claim 8, wherein the first model generation unit is further configured to receive an impedance distribution of a learning battery for frequencies of an entire range, generate a basic equivalent circuit of the learning battery from the impedance distribution, identify a characteristic frequency component corresponding to at least one predefined characteristic impedance area in the impedance distribution, and generate training data in which the characteristic impedance component and the characteristic frequency component are labeled as the basic equivalent circuit.

10. The battery diagnosis apparatus of claim 7, further comprising:
a second model configured to output a battery state when receiving physical characteristic information; and
a diagnosis unit configured to determine a battery state of the target battery by inputting physical characteristic information identified by analyzing the predicted equivalent circuit to the second model.

11. The battery diagnosis apparatus of claim 10, further comprising a second model generation unit configured to train the second model by using training data in which physical characteristic information identified by analyzing the basic equivalent circuit is labeled as a battery state of the learning battery.

12. An non-transitory computer-readable recording medium having recorded thereon a computer program for performing the battery diagnosis method of claim 1.
